(19) United States
(12) Patent Application Publication
(10) Pub. No.: US 2020/0350297 A1
(43) Pub. Date: Nov. 5, 2020

(54) LIGHT EMITTING DEVICE AND METHOD FOR MAKING THE SAME

(71) Applicant: APT ELECTRONICS CO. LTD., Guangdong (CN)

(72) Inventors: Chuiming WAN, Guangdong (CN); Zhaoming ZENG, Guangdong (CN); Shuguang YAO, Guangdong (CN); ChiWing KEUNG, Guangdong (CN); Guowei David XIAO, Guangdong (CN)

(21) Appl. No.: 16/934,549

(22) Filed: Jul. 21, 2020

Related U.S. Application Data
(63) Continuation of application No. PCT/CN2018/124160, filed on Dec. 27, 2018.

(30) Foreign Application Priority Data
Dec. 10, 2018 (CN) 201811502899.1

(51) Int. Cl. H01L 25/075; H01L 33/50

(52) U.S. Cl. CPC H01L 25/0753; H01L 33/507; H01L 33/26; H01L 33/504; H01L 2933/0041; H01L 33/502

(57) ABSTRACT

A light emitting device, including a carrier, at least one first light-emitting diode fixed on the carrier for emitting a first color light, at least one second light-emitting diode fixed on the carrier for emitting a second color light, a first light converter coated on at least one first light-emitting diode for converting the first color light into a red light, and a second light converter coated on at least one second light-emitting diode for converting the second color light into a third color light. The first color light, the red light, the second color light and the third color light are mixed into a sunlight-like light. The light emitting device and method effectively enhance the light emission intensity of the red light, and solve the problems of the existing sunlight-like light, e.g. insufficient red light intensity or absence of red light.

### CROSS-REFERENCE TO RELATED APPLICATIONS

This application claims priority to PCT Application No. PCT/CN2018/124160, having a filing date of Dec. 27, 2018, which is based on Chinese Application No. 201811502899.1, having a filing date of Dec. 10, 2018, the entire content of which is hereby incorporated by reference.

### FIELD OF TECHNOLOGY

The following relates to a field of light emitting device, in particular, a light emitting device and a method for making the same.

### BACKGROUND

Sunlight is the most important natural light source, and it is white due to its uniform energy distribution in the visible spectrum. In addition to being able to meet people's needs in daily production, work, and life, the long-wavelength red light in the visible light range of sunlight also has the strongest penetration, which has a warming effect on skin and mucous membranes, and can strongly stimulate blood flow, improve blood circulation, enhance the vitality of human cells, promote human metabolism and protein synthesis.

Sunlight-like light emitting device has been produced in order to satisfy people who want to enjoy the sunlight at night or indoors. Existing sunlight-like light-emitting device is generally composed of red light-emitting diode (LED) chip, blue-violet LED chip and phosphor, wherein red light is emitted by red LED chip, blue-violet light emitted by blue-violet LED chip, thereby white light is produced by mixing both lights through phosphors. However, because the large difference in thermal drift performance and thermal state light decay between the red LED chip and the blue-violet LED chip, under the same thermal state, the red LED chip will undergo a serious thermal drift, causing the color of the red light emitted by the red LED chip drifts too, and then the white light formed is drifted in color. Therefore, the existing sunlight-like light emitting device has defects of insufficient intensity or absent of red light.

### SUMMARY OF INVENTION

An aspect relates to a light emitting device and a method for making the light emitting device, which can effectively enhance the light emitting intensity of the red light, and prevent the existing sunlight-like light emitting device from the insufficient intensity or absent of red light.

Provided is a light emitting device, comprising:

a carrier for carrying a light-emitting diode;
at least one first light-emitting diode fixed on the carrier, for emitting a first color light;
at least one second light-emitting diode fixed on the carrier, for emitting a second color light;
a first light converter coated on the at least one first light-emitting diode, for converting the first color light into a red light; and
a second light converter coated on the at least one second light-emitting diode, for converting the second color light into a third color light; wherein
the first color light, the red light, the second color light and the third color light are mixed into a sunlight-like light.

The first light-emitting diode comprises a blue LED chip, and the second light-emitting diode comprises a violet LED chip.

The first light converter comprises deep red phosphors, and the second light converter comprises blue phosphors, cyan phosphors, yellow-green phosphors, orange phosphors and red phosphors.

Further, the first light converter comprises deep red phosphors and red phosphors, and the second light converter comprises blue phosphors, cyan phosphors, yellow-green phosphors and orange phosphors.

Furthermore, the first light converter comprises deep red phosphors and orange phosphors, and the second light converter comprises blue phosphors, cyan phosphors, yellow-green phosphors and red phosphors.

Furthermore, the first light converter comprises deep red phosphors, orange phosphors and red phosphors, and the second light converter comprises blue phosphors, cyan phosphors and yellow-green phosphors.

The proportion of the phosphors in the first light converter is 5%-20% of the total amount of the phosphors in both the first light converter and the second light converter.

Semiconductors materials of the blue LED chip and the violet LED chip comprise group III-VI elements.

The first light-emitting diode and the second light-emitting diode are configured at intervals so that the light emitted by the two light-emitting diodes can be mixed uniformly.

The light emitting device further comprises a reflector cup which is configured on the side of the carrier for reflecting the light back.

Both the first light converter and the second light converter comprise a transparent sealant and a matrix, rare earth ions or transition metal ions are doped into the matrix of the first light converter, and one or two ions selected from Ce³⁺ and Eu²⁺ are doped to the matrix of the second light converter.

Further, the matrixes are distributed in the transparent sealant, and the matrix comprises one or more combinations selected from Y₃Al₅O₁₂, Lu₃Al₅O₁₂, Sr₅(PO₄)₃Cl, SiAlON, nitride, gallium oxide and silicate.

A method for making the light emitting device is also provided, which comprises the following steps:

Fixing at least one first light-emitting diode and at least one second light-emitting diode on a carrier, wherein the first light-emitting diode is used to emit a first color light, and the second light-emitting diode is used to emit a second color light;

Electrically connecting the at least one first light-emitting diode and the at least one second light-emitting diode to the carrier by wire bonding;

Dispensing a first light converter on the first light-emitting diode, and the first light converter is used to convert the first color light into a red light;

Dispensing a second light converter on the second light-emitting diode, and the second light converter is used to convert the second color light into a third color light; and

Heating and curing the combination of the first light converter and the second light converter as a whole to obtain a light emitting device.

The light emitting device and the method of the present invention have the following advantages:

The first light-emitting diode is coated by the first light converter to produce a red light, preventing the red light from drifting in color and enhancing the light emission intensity of red light, while the second light-emitting diode is coated by the second light converter in order to excite lights in other wavelength range of sunlight-like light, then the first color light, the red light, the second color light and the third color light is mixed into a sunlight-like light, which can effectively enhance the light emission intensity of red light, so that the spectrum of the sunlight-like light mixed by the light emitting device has a higher degree of coincidence with the spectrum of sunlight, and the color rendering properties of the light emitting device is significantly improved.

### BRIEF DESCRIPTION OF DRAWINGS

The embodiments of the present disclosure will be described hereinafter with reference to the following figures, wherein:

FIG. 1 is a spectrogram of the sunlight-like light emitted by the existing sunlight-like light emitting device.

FIG. 2 depicts a structurally schematic view of a light emitting device in accordance with Embodiment 1 of the present invention.

FIG. 3 depicts a structurally schematic view of a light emitting device in accordance with Embodiment 2 of the present invention.

FIG. 4 depicts a structurally schematic view of a light emitting device in accordance with Embodiment 3 of the present invention.

FIG. 5 depicts a structurally schematic view of a light emitting device in accordance with Embodiment 4 of the present invention.

FIG. 6 depicts a structurally schematic view of a light emitting device in accordance with Embodiment 5 of the present invention.

FIG. 7 is a spectrogram showing the spectrum of both the existing sunlight-like light emitting device and the light emitting device in the present invention.

### DETAILED DESCRIPTION

The present invention will be described hereinafter in details with reference to the figures and the embodiments for the sake of better understanding. The present invention can be implemented in many different forms and is not limited to the embodiments described in this disclosure. Any non-substantive, obvious alterations or improvement by the technician of this technical field according to the present invention may be incorporated into ambit of claims of the present invention.

As shown in FIG. 1, in the existing sunlight-like light emitting device, because the large difference in thermal drift performance and thermal state light decay between the red LED chip and the blue-violet LED chip, under the same thermal state, the red LED chip will undergo a serious thermal drift, causing the color of the red light emitted by the red light LED chip drifts, which makes the insufficient red light intensity. In the present invention, a first light-emitting diode is coated with a first light converter, and a red light is excited from the first light converter in order to enhance the intensity of the red light, and effectively solve the current defects of insufficient red light intensity or absent of red light.

### Embodiment 1

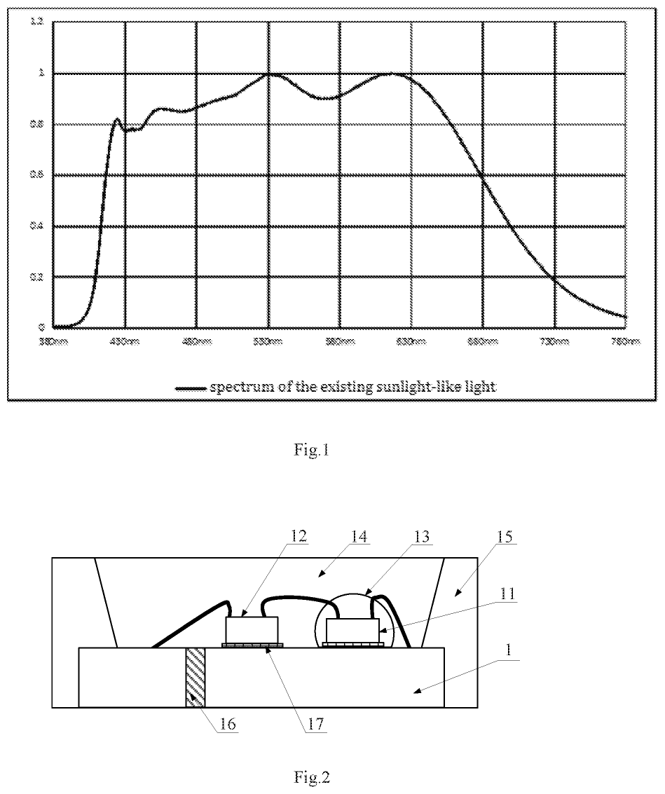

FIG. 2 depicts a structurally schematic view of a light emitting device in accordance with this embodiment.

As shown in FIG. 2, the light emitting device comprises a carrier 1, at least one first light-emitting diode 11 fixed on the carrier 1 for emitting a first color light, at least one second light-emitting diode 12 fixed on the carrier 1 for emitting a second color light, a first light converter 13 coated on the at least one first light-emitting diode 11 for converting the first color light into a red light, and a second light converter 14 coated on the at least one second light-emitting diode 12 and the first light converter 13 for converting the second color light into a third color light. The first color light, the red light, the second color light and the third color light are mixed into a sunlight-like light.

The first light-emitting diode 11 and the second light-emitting diode 12 are both electrically connected to the carrier 1 by wire bonding.

The light emitting process of the light emitting device is as follows: the first light-emitting diode 11 emits a first color light, wherein part of the first color light is transmitted through and out of the first light converter 13 and the rest of the first color light is converted into a red light by the first light converter 13, and the second light-emitting diode 12 emits a second color light, wherein part of the second color light is transmitted through and out of the second light converter 14, and the rest of the second color light is converted into a third color light by the second light converter 14, then the first color light, the red light, the second color light and the third color light in the light emitting device are mixed into a sunlight-like light. As shown in FIG. 2, the first light-emitting diode 11 and the first light converter 13 coated thereon can effectively enhance the red light intensity of the light emitting device, so that the spectrum of the white light emitted by the light emitting device has a higher degree of coincidence with the spectrum of sunlight, so the white light emitted by the light emitting device is more similar to sunlight.

Compared to the prior art, in the light emitting device of the present invention, the first light-emitting diode 11 is coated by the first light converter 13 to produce a red light, preventing the red light from drifting in color and enhancing the light emission intensity of red light, while the second light-emitting diode 12 is coated by the second light converter 14 in order to excite lights in other wavelength range of sunlight-like light, then the first color light, the red light, the second color light and the third color light is mixed into a sunlight-like light, which can effectively enhance the light emission intensity of red light, so that the spectrum of the sunlight-like light mixed by the light emitting device has a higher degree of coincidence with the spectrum of sunlight, and the color rendering properties of the light emitting device is significantly improved.

Preferably, the first light-emitting diode 11 comprises a blue LED chip, and the second light-emitting diode 12 comprises a violet LED chip. Due to the small difference in thermal drift performance and thermal state light decay between the blue LED chip and the violet LED chip, under the same thermal state, it can prevent the blue LED chip and the violet LED chip from the thermal drift effectively, then prevent the violet color and the blue color from drifting in color, to improve light emission efficiency. Where the blue LED chip has a blue emission at 440-460 nm, and the violet LED chip has a violet emission at 365-425 nm.

Further, the semiconductor materials in the blue LED chip and the violet LED chip in the light emitting device comprise group III-VI elements. Because the blue LED chip and the violet LED chip are made of the semiconductor materials in same material system, the blue LED chip and the violet LED chip have the same thermal stability, which can further reduce the difference in thermal drift and thermal light decay between the two LED chips, and improve light emission efficiency.

Alternatively, the first light converter 13 comprises deep red phosphors, and the second light converter 14 comprises blue phosphors, cyan phosphors, yellow-green phosphors, orange phosphors and red phosphors. When the blue light emitted by the blue LED chip transmits through the first light converter 13, it excites the deep red phosphors to generate a deep red light when it. When the violet light emitted by the violet LED chip transmits through the second light converter 14, it excites the blue phosphors, the cyan phosphors, the yellow-green phosphors, the orange phosphors and the red phosphors to produce a blue light, a cyan light, a yellow-green light, an orange light and a red light respectively, then the blue light, the deep red light, the violet light, the cyan light, the yellow-green light, the orange light and the red light are mixed into a white-like light. Since the first light converter 13 only contains the deep red phosphor, the blue light emitted by the blue LED chip can excite the first light converter 13 to emit a deep red light, which can effectively enhance the intensity of the red light.

Alternatively, the first light converter 13 comprises deep red phosphors and orange phosphors, and the second light converter 14 comprises blue phosphors, cyan phosphors, yellow-green phosphors and red phosphors. When the blue light emitted by the blue LED chip transmits through the first light converter 13, it excites the deep red phosphors and the orange phosphors to generate a deep red light and an orange light respectively. When the violet light emitted from the violet LED chip transmits through the second light converter 14, it excites the blue phosphors, the cyan phosphors, the yellow-green phosphors and the red phosphors to generate a blue light, a cyan light, a yellow-green light and a red light respectively, then the blue light, the deep red light, the orange light, the violet light, the cyan light, the yellow-green light and the red light are mixed into a white-like light. Since the first light converter 13 contains the deep red phosphors and the orange phosphors, the blue light emitted by the blue LED chip can excite the first light converter 13 to emit a deep red light and an orange light, which can effectively enhance the intensity of the red light.

Alternatively, the first light converter 13 comprises deep red phosphors and red phosphors, and the second light converter 14 comprises blue phosphors, cyan phosphors, yellow-green phosphors and orange phosphors. When the blue light emitted by the blue LED chip transmits through the first light converter 13, it excites the deep red phosphors and the red phosphors to generate a deep red light and a red light respectively. When the violet light emitted from the violet LED chip transmits through the second light converter 14, it excites the blue phosphors, the cyan phosphors, the yellow-green phosphors and the orange phosphors to generate a blue light, a cyan light, a yellow-green light and an orange light respectively, then the blue light, the deep red light, the red light, the violet light, the cyan light, the yellow-green light and the orange light are mixed into a white-like light. Since the first light converter 13 contains the deep red phosphors and the red phosphors, the blue light emitted by the blue LED chip can excite the first light converter 13 to emit a deep red light and a red light, which can effectively enhance the intensity of red light, and especially the deep red light.

Alternatively, the first light converter 13 comprises deep red phosphors, red phosphors and orange phosphors, and the second light converter 14 comprises blue phosphors, cyan phosphors and yellow-green phosphors. When the blue light emitted by the blue LED chip transmits through the first light converter 13, it excites the deep red phosphors, the red phosphors and the orange phosphors to generate a deep red light, a red light and an orange light respectively. When the violet light emitted from the violet LED chip transmits through the second light converter 14, it excites the blue phosphors, the cyan phosphors, and the yellow-green phosphors to generate a blue light, a cyan light and a yellow-green light, then the blue light, the deep red light, the red light, the orange light, the violet light, the cyan light and the yellow-green light are mixed into a white-like light. Since the first light converter 13 contain the deep red phosphors, the red phosphors and the orange phosphors, the blue light emitted by the blue LED chip can excite the first light converter 13 to emit a deep red light, a red light and an orange light, which can effectively enhance the intensity of red light, and especially the deep red light, while prevent the blue light emitted by the blue phosphors and the cyan light emitted by the cyan phosphors from being absorbed by the deep red phosphors, the red phosphors or the orange phosphors, thus the light emission intensity of the blue light and the cyan light is enhanced.

Preferably, the proportion of the phosphors in the first light converter 13 is 5%-20% of the total amount of the phosphors in both the first light converter 13 and the second light converter 14. The proportion of the phosphors in the first light converter 13 can be adjusted to control the brightness of the red light. In the above-described embodiment, since the first light converter 13 comprises the deep red phosphors, the deep red luminescence at the wavebands of larger than 700 nm can be improved by the light emitting device. As shown in FIG. 7, the light emission intensity of the sunlight-like light emitted by the light emitting device of the present invention changes with wavelength, wherein the light emission intensity begin to increases gradually from the wavelength of 400 nm, and stabilizes in the wavelength range of 425 nm-445 nm, then slowly increases from the wavelength of 445 nm until the maximum light emission intensity is reached at the wavelength range of 500 nm-650 nm. After that, the light emission intensity begins to decrease gradually from the wavelength of 650 nm and then decrease smoothly from the wavelength of 710 nm, and approaches to around zero at the wavelength of 800 nm. The visible spectrum of the sunlight-like light emitted by the light emitting device is continuous, and the light emission intensity of its red light is higher than that of the existing sunlight-like light. The light emission intensity of the light emitted by the light emitting device in the wavelength range of 410 nm-710 nm is no less than 60% of the maximum light emission intensity, which makes it more similar to the spectrum of natural sunlight. In addition, in the color rendering index of the sunlight-like light emitted by the light emitting device of the present invention, Ra value is no less than 95, Rf value is no less than 96, and CQS value is no less than 85, which leads to the excellent color rendering properties.

In the light emitting device of the present invention, the phosphors in the first light converter and the second light converter can also be provided on the first light-emitting diode and the second light-emitting diode in the form of a phosphor layer, and this will be described hereinafter in details with reference to Embodiments 2 to 4.

### Embodiment 2

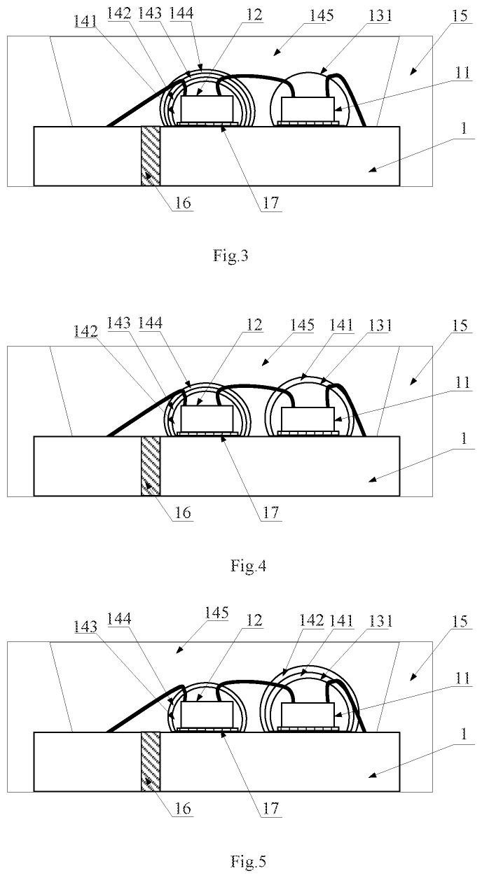

FIG. 3 depicts a structurally schematic view of a light emitting device in accordance with this embodiment.

As shown in FIG. 3, the light emitting device of this embodiment comprises all the components described in Embodiment 1, except that, the first light converter 13 comprises a deep red phosphor layer 131, and the second light converter 14 comprises a red phosphor layer 141, an orange phosphor layer 142, a yellow-green phosphor layer 143, a cyan phosphor layer 144 and a blue phosphor layer 145. When the blue light emitted by the blue LED chip transmits through the first light converter 13, it excites the deep red phosphor layer 131 to generate a deep red light. When the violet light emitted by the violet LED chip transmits through the second light converter 14, it excites the red phosphor layer 141, the orange phosphor layer 142, the yellow-green phosphor layer 143, the cyan phosphor layer 144 and the blue phosphor layer 145 to generate a red light, an orange light, a yellow-green light, a cyan light and a blue light respectively, and then the blue light, the deep red light, the violet light, the red light, the orange light, the yellow-green light and the cyan light are mixed into a white-like light. Since the first light converter 13 only contains the deep red phosphor layer 131 made of the deep red phosphors, thus the blue light emitted by the blue LED chip can excite the first light converter 13 to emit a deep red light, which can effectively enhance the intensity of red light.

The phosphor layers of various colors in the first light converter 13 and the second light converter 14 can be respectively stacked in different arrangements.

### Embodiment 3

FIG. 4 depicts a structurally schematic view of a light emitting device in accordance with this embodiment.

As shown in FIG. 4, the light emitting device of this embodiment comprises all the components described in Embodiment 1, except that, the first light converter 13 comprises a deep red phosphor layer 131 and a red phosphor layer 141, and the second light converter 14 comprises an orange phosphor layer 142, a yellow-green phosphor layer 143, a cyan phosphor layer 144 and a blue phosphor layer 145. When the blue light emitted by the blue LED chip transmits through the first light converter 13, it excites the deep red phosphor layer 131 and the red phosphors layer 141 to generate a deep red light and a red light respectively. When the violet light emitted by the violet LED chip transmits through the second light converter 14, it excites the orange phosphor layer 142, the yellow-green phosphor layer 143, the cyan phosphor layer 144 and the blue phosphor layer 145 to generate an orange light, a yellow-green light, a cyan light and a blue light respectively, and then the blue light, the deep red light, the red light, the violet light, the orange light, the yellow-green light and the cyan light are mixed into a white-like light. Since the first light converter 13 contains the deep red phosphor layer 131 and the red phosphor layer 141 that both are made of the deep red phosphors and the red phosphors respectively, thus the blue light emitted by the blue LED chip can excite the first light converter 13 to emit a deep red light and a red light, which can effectively enhance the intensity of red light.

It can be understood that the first light converter 13 may comprise the deep red phosphor layer 131 and the orange phosphor layer 142, and the second light converter 14 may comprise the red phosphor layer 141, the yellow-green phosphor layer 143, the cyan phosphor layer 144 and the blue phosphor layer 145, the principle of light emission in this case can refer to Embodiment 1, and the various phosphor layers in the first light converter 13 and the second light converter 14 can be respectively stacked in different arrangements.

### Embodiment 4

FIG. 5 depicts a structurally schematic view of a light emitting device in accordance with this embodiment.

As shown in FIG. 5, the light emitting device of this embodiment comprises all the components described in Embodiment 1, except that, the first light converter 13 comprises a deep red phosphor layer 131, a red phosphor layer 141 and an orange phosphor layer 142, and the second light converter 14 comprises a yellow-green phosphor layer 143, a cyan phosphor layer 144 and a blue phosphor layer 145. When the blue light emitted by the blue LED chip transmits through the first light converter 13, it excites the deep red phosphor layer 131, the red phosphors layer 141 and the orange phosphor layer 142 to generate a deep red light, a red light and a orange light respectively. When the violet light emitted by the violet LED chip transmits through the second light converter 14, it excites the yellow-green phosphor layer 143, the cyan phosphor layer 144 and the blue phosphor layer 145 to generate a yellow-green light, a cyan light and a blue light respectively, and then the blue light, the deep red light, the red light, the orange light, the violet light, the yellow-green light and the cyan light are mixed into a white-like light. Since the first light converter 13 contains the deep red phosphor layer 131, the red phosphor layer 141 and the orange phosphor layer 142, that are made of the deep red phosphors, the red phosphors and the orange phosphors respectively, thus the blue light emitted by the blue LED chip can excite the first light converter 13 to emit a deep red light, a red light and a orange light, which can effectively enhance the intensity of red light, and especially the deep red light, while can also prevent the blue light from the blue phosphor layer and the cyan light from the cyan phosphor layer from being absorbed by the deep red phosphor layer, the red phosphor layer or the orange phosphor layer, thus the light emission intensity of the blue light and the cyan light is enhanced.

In the Embodiments 2-4, the first light converter 13 comprises the deep red phosphor layer 131, which makes the light emitting device to increase the intensity of the deep red luminescence at the wavebands of larger than 700 nm effectively. As shown in FIG. 7, the light emission intensity of the sunlight-like light emitted by the light emitting device of the present invention changes with wavelength, wherein the light emission intensity begins to increase gradually from the wavelength of 400 nm, and stabilize in the wavelength range of 425 nm-445 nm, then slowly increases from the wavelength of 445 nm until the maximum light emission intensity is reached at the wavelength range of 500 nm-650 nm. After that, the light emission intensity begin to decreases gradually from the wavelength of 650 nm and then decreases smoothly from the wavelength of 710 nm and approaches to around zero at the wavelength of 800 nm. The visible spectrum of the sunlight-like light emitted by the light emitting device is continuous, and the light emission intensity of its red-light range is high than that of the existing sunlight-like light. The light emission intensity of the light emitted by the light emitting device in the wavelength range of 410 nm-710 nm is no less than 60% of the maximum light emission intensity, which makes it more similar to the spectrum of natural sunlight. In addition, in the color rendering index of the sunlight-like light emitted by the light emitting device of the present invention, Ra value is no less than 95, Rf value is no less than 96, and CQS value is no less than 85, which leads to the excellent color rendering properties.

In the Embodiments 2 to 4, when the phosphor layers coated on the blue LED chip are stacked from bottom to top in the order of the light emission wavelength of the phosphor layer from short to long, the phosphor layer with longer emission wavelength will absorb the light emitted by the phosphor layer with shorter wavelength, which will reduce the light emission efficiency of the light emitting device. Therefore, the preferred solution of the above embodiments is that the phosphor layers coated on the blue LED chip are stacked from bottom to top in the order of the light emission wavelength of the phosphor layer from long to short, which can reduce the absorption of light by the phosphor layers and improve the light emission efficiency.

Further, as shown in FIGS. 2-6, in order to improve the light emission efficiency of the light emitting device, the light emitting device further comprises a reflector cup 15 which is configured on the side of the carrier 1 for reflecting the light back.

Further, as shown in FIGS. 2-6, the carrier 1 comprises a first carrier and a second carrier, and an insulating separator 16 is provided between the first carrier and the second carrier. The first electrode of the first light-emitting diode 11 is connected to the first carrier, the second electrode of the first light-emitting diode 11 is connected to the first electrode of the second light-emitting diode 12, and the second electrode of the second light-emitting diode 12 is connected to the second carrier.

### Embodiment 5

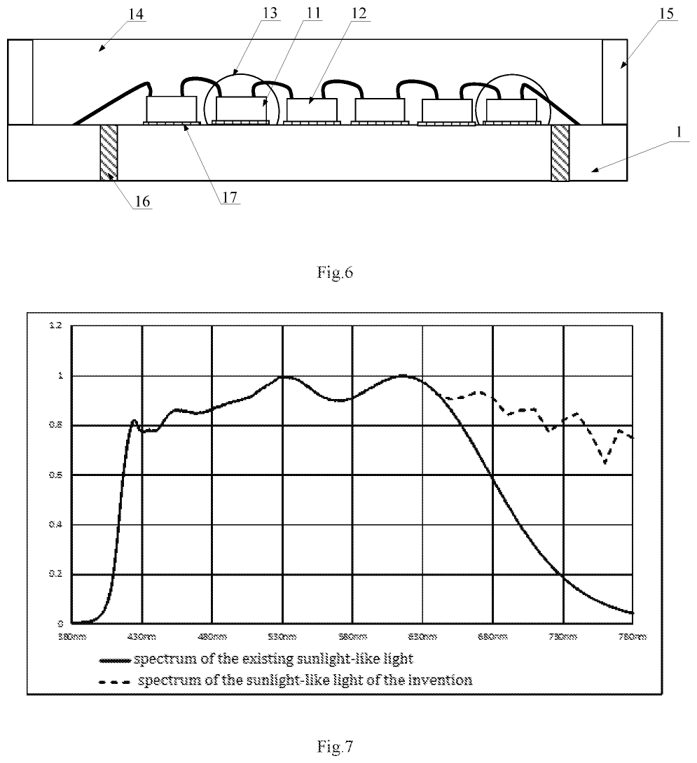

As shown in FIG. 6, the light emitting device of this embodiment comprises all the components described in Embodiment 1, except that, the light emitting device comprises a plurality of first light-emitting diodes 11 and a plurality of second light-emitting diodes 12, which can enhance the light emission intensity of the light emitting device. Meanwhile the first light-emitting diode 11 and the second light-emitting diode 12 are configured at intervals so that the light emitted by the two can be mixed uniformly.

For example, in this embodiment, a first light-emitting diode 11 can be arranged between two second light-emitting diodes 12 for the sake of uniform light mixture. Alternatively the number of the first light-emitting diodes 11 and the second light-emitting diodes 12 can be set in a certain ratio, for example, as shown in FIG. 6, the ratio of the first light-emitting diode 11 to the second light-emitting diode 12 is 2 to 4, such that all of light emitted by the first light-emitting diodes 11 and the second light-emitting diodes 12 can be mixed uniformly, with the light reflection from the reflector cup 15.

### Embodiment 6

Provided is a method for making a light emitting device, comprising the following steps:

Fixing at least one first light-emitting diode and at least one second light-emitting diode on a carrier, wherein the first light-emitting diode is used to emit a first color light, and the second light-emitting diode is used to emit a second color light;

Electrically connecting the at least one first light-emitting diode and the at least one second light-emitting diode to the carrier by wire bonding;

Dispensing a first light converter on the first light-emitting diode, the first light converter is used to convert the first color light into a red light;

Dispensing a second light converter on the second light-emitting diode, the second light converter is used to convert the second color light into a third color light;

Heating and curing the combination of the above-mentioned first light converter and the second light converter as a whole to obtain a light emitting device.

Compared to the prior art, in the method for making the light emitting device, the first light-emitting diode is coated by the first light converter to produce a red light, preventing the red light from drifting in color and enhance the light emission intensity of red light, while the second light-emitting diode is coated by the second light converter in order to excite lights in other wavelength range of sunlight-like light, then the first color light, the red light, the second color light and the third color light is mixed into a sunlight-like light, which can effectively enhance the light emission intensity of red light, so that the spectrum of the sunlight-like light mixed by the light emitting device has a higher degree of coincidence with the spectrum of sunlight, and the color rendering properties of the light emitting device is significantly improved.

Preferably, the first light-emitting diode comprises a blue LED chip, and the second light-emitting diode comprises a violet LED chip. Due to the small difference in thermal drift performance and thermal state light decay between the blue LED chip and the violet LED chip, under the same thermal state, it can prevent the blue LED chip and the violet LED chip from the thermal drift effectively, then prevent the violet color and the blue color from drifting in color, to improve light emission efficiency. Where the blue LED chip has a blue light emission at 440˜460 nm, and the violet LED chip has a violet light emission at 365˜425 nm.

Further, the semiconductor materials in the blue LED chip and the violet LED chip in the light emitting device comprise group III-VI elements. Because the blue LED chip and the violet LED chip are made of the semiconductor materials in the same material system, the blue LED chip and the violet LED chip have the same thermal stability, which can further reduce the difference in thermal drift and thermal light decay between the two LED chips, and improve light emission efficiency.

Alternatively, the first light converter comprises deep red phosphors, and the second light converter comprises blue phosphors, cyan phosphors, yellow-green phosphors, orange phosphors, and red phosphors. When the blue light emitted by the blue LED chip transmits through the first light converter, it excites the deep red phosphors to generate a deep red light. When the violet light emitted by the violet LED chip transmits through the second light converter, it excites the blue phosphors, the cyan phosphors, the yellow-green phosphors, the orange phosphors and the red phosphors to produce a blue light, a cyan light, a yellow-green light, an orange light and a red light respectively, then the blue light, the deep red light, the violet light, the cyan light, the yellow-green light, the orange light and the red light are mixed into a white-like light. Since the first light converter only contains the deep red phosphor, the blue light emitted by the blue LED chip can excite the first light converter 13 to emit a deep red light, which can effectively enhance the intensity of the red light.

Alternatively, the first light converter comprises deep red phosphors and orange phosphors, and the second light converter comprises blue phosphors, cyan phosphors, yellow-green phosphors and red phosphors. When the blue light emitted by the blue LED chip transmits through the first light converter, it excites the deep red phosphors and the orange phosphors to generate a deep red light and an orange light respectively. When the violet light emitted from the violet LED chip transmits through the second light converter, it excites the blue phosphors, the cyan phosphors, the yellow-green phosphors and the red phosphors to generate a blue light, a cyan light, a yellow-green light and a red light respectively, then the blue light, the deep red light, the orange light, the violet light, the cyan light, the yellow-green light and the red light are mixed into a white-like light. Since the first light converter contains the deep red phosphors and the orange phosphors, the blue light emitted by the blue LED chip can excite the first light converter 13 to emit a deep red light and an orange light, which can effectively enhance the intensity of the red light.

Alternatively, the first light converter comprises deep red phosphors and red phosphors, and the second light converter comprises blue phosphors, cyan phosphors, yellow-green phosphors and orange phosphors. When the blue light emitted by the blue LED chip transmits through the first light converter, it excites the deep red phosphors and the red phosphors to generate a deep red light and a red light respectively. When the violet light emitted from the violet LED chip transmits through the second light converter, it excites the blue phosphors, the cyan phosphors, the yellow-green phosphors and the orange phosphors to generate a blue light, a cyan light, a yellow-green light and an orange light respectively, then the blue light, the deep red light, the red light, the violet light, the cyan light, the yellow-green light and the orange light are mixed into a white-like light. Since the first light converter 13 only contains the deep red phosphors and the red phosphors, the blue light emitted by the blue LED chip can excite the first light converter 13 to emit a deep red light and a red light, which can effectively enhance the intensity of red light, and especially the deep red light.

Alternatively, the first light converter comprises deep red phosphors, red phosphors and orange phosphors, and the second light converter comprises blue phosphors, cyan phosphors, and yellow-green phosphors. When the blue light emitted by the blue LED chip transmits through the first light converter, it excites the deep red phosphors, the red phosphors and the orange phosphors to generate a deep red light, a red light and an orange light respectively. When the violet light emitted from the violet LED chip transmits through the second light converter, it excites the blue phosphors, the cyan phosphors and the yellow-green phosphors to generate a blue light, a cyan light, a yellow-green light and an orange light respectively, then the blue light, the deep red light, the red light, the orange light, the violet light, the cyan light and the yellow-green light are mixed into a white-like light. Since the first light converter 13 contain the deep red phosphors, the red phosphors and the orange phosphors, the blue light emitted by the blue LED chip can excite the first light converter to emit a deep red light, a red light and an orange light, which can effectively enhance the intensity of red light, and especially the deep red light, while prevent the blue light emitted by the blue phosphors and the cyan light emitted by the cyan phosphors from being absorbed by the deep red phosphors, the red phosphors or the orange phosphors, thus the light emission intensity of the blue light and the cyan light is enhanced.

Preferably, the proportion of the phosphors in the first light converter is 5-20% of the total amount of the phosphors in both the first light converter and the second light converter. The proportion of the phosphors in the first light converter can be adjusted to control the brightness of the red light.

Preferably, both the first light converter and the second light converter comprise a transparent sealant and a matrix. The rare earth ions or transition metal ions are doped into the matrix of the first light converter, as the activated ions of the luminophor. One or two ions selected from Ce³⁺ and Eu²⁺ are doped into the matrix of the second light converter, as the activated ions of the luminophor. Where the rare earth ions comprise one or more ions selected from Pr, Tb, Eu, Dy, Nd and Sm, and the transition metal ions comprise one or more ions selected from of Cr, Ti, V, Ni, and Cu.

Furthermore, the matrixes are distributed in the transparent sealant, and the matrix comprises one or more combinations selected from Y₃Al₅O₁₂, Lu₃Al₅O₁₂, Sr₅(PO₄)₃Cl, SiAlON, nitride, gallium oxide and silicate.

The embodiment described hereinbefore is merely preferred embodiment of the present invention and not for purposes of any restrictions or limitations on the invention. It will be apparent that any non-substantive, obvious alterations or improvement by the technician of this technical field according to the present invention may be incorporated into ambit of claims of the present invention.

For the sake of clarity, it is to be understood that the use of ‘a’ or ‘an’ throughout this application does not exclude a plurality, and ‘comprise’ or ‘comprising’ do not exclude other steps or elements.

What is claimed is:

1. Light emitting device, comprising:
a carrier for carrying a light-emitting diode;
at least one first light-emitting diode fixed on the carrier, for emitting a first color light;
at least one second light-emitting diode fixed on the carrier, for emitting a second color light;
a first light converter coated on the at least one first light-emitting diode, for converting the first color light into a red light; and
a second light converter coated on the at least one second light-emitting diode, for converting the second color light into a third color light; wherein
the first color light, the red light, the second color light and the third color light are mixed into a sunlight-like light.

2. The light emitting device of claim 1, wherein the first light-emitting diode comprises a blue LED chip, and the second light-emitting diode comprises a violet LED chip.

3. The light emitting device of claim 2, wherein
the first light converter comprises deep red phosphors, and the second light converter comprises blue phosphors, cyan phosphors, yellow-green phosphors, orange phosphors and red phosphors, or
the first light converter comprises deep red phosphors and red phosphors, and the second light converter comprises blue phosphors, cyan phosphors, yellow-green phosphors and orange phosphors, or
the first light converter comprises deep red phosphors and orange phosphors, and the second light converter comprises blue phosphors, cyan phosphors, yellow-green phosphors and red phosphors.

4. The light emitting device of claim 2, wherein the first light converter comprises deep red phosphors, orange phosphors and red phosphors, and the second light converter comprises blue phosphors, cyan phosphors and yellow-green phosphors.

5. The light emitting device of claim 3, wherein the proportion of the phosphors in the first light converter is 5%-20% of the total amount of the phosphors in both the first light converter and the second light converter.

6. The light emitting device of claim 4, wherein the proportion of the phosphors in the first light converter is 5%-20% of the total amount of the phosphors in both the first light converter and the second light converter.

7. The light emitting device of claim 2, wherein a semiconductor material in the blue LED chip and the violet LED chip comprises group III-VI elements.

8. The light emitting device of claim 1, wherein the first light-emitting diode and the second light-emitting diode are configured at intervals so that the light emitted by the two light-emitting diodes can be mixed uniformly.

9. The light emitting device of claim 1, wherein both the first light converter and the second light converter comprise a transparent sealant and a matrix, rare earth metal ions or transition metal element ions are doped to the matrix of the first light converter, and one or two ions selected from Ce³⁺ and Eu²⁺ are doped to the matrix of the second light converter.

10. The light emitting device of claim 9, wherein the matrixes are distributed in the transparent sealant, and the matrix comprises one or more combinations selected from Y₃Al₅O₁₂, Lu₃Al₅O₁₂, Sr₅(PO₄)₃Cl, SiAlON, nitride, gallium oxide and silicate.

11. A method for making a light emitting device, comprising the following steps:
Fixing at least one first light-emitting diode and at least one second light-emitting diode on a carrier, wherein the first light-emitting diode is used to emit a first color light, and the second light-emitting diode is used to emit a second color light;
Electrically connecting the at least one first light-emitting diode and the at least one second light-emitting diode to the carrier by wire bonding;
Dispensing a first light converter on the first light-emitting diode, and the first light converter is used to convert the first color light into a red light;
Dispensing a second light converter on the second light-emitting diode, and the second light converter is used to convert the second color light into a third color light; and
Heating and curing the combination of the first light converter and the second light converter as a whole to obtain a light emitting device.
